(19) United States
(12) Patent Application Publication
(10) Pub. No.: US 2024/0209508 A1
(43) Pub. Date: Jun. 27, 2024

(54) DEPOSITION APPARATUS AND PROCESSING METHOD

(71) Applicant: Tokyo Electron Limited, Tokyo (JP)

(72) Inventor: Manabu HONMA, Iwate (JP)

(21) Appl. No.: 18/536,813

(22) Filed: Dec. 12, 2023

(30) Foreign Application Priority Data
Dec. 22, 2022 (JP) 2022-205690

(51) Int. Cl. C23C 16/458; C23C 16/455; C23C 16/46

(52) U.S. Cl. CPC C23C 16/4584; C23C 16/45572; C23C 16/463

(57) ABSTRACT

A deposition apparatus includes a processing chamber, a rotary table rotatably provided in the processing chamber and including a coolant flow channel therein, a plurality of stages provided along a rotation direction of the rotary table and each configured to mount a substrate thereon, and a heater configured to heat the substrate mounted on each of the stages. The stages are supported by the rotary table while being thermally isolated from the rotary table.

### CROSS-REFERENCE TO RELATED APPLICATIONS

This application is based on and claims priority to Japanese Patent Application No. 2022-205690, filed on Dec. 22, 2022, the entire contents of which are incorporated herein by reference.

### BACKGROUND OF THE INVENTION

### 1. Field of the Invention

The disclosure herein relates a deposition apparatus and a processing method.

### 2. Description of the Related Art

Japanese Laid-open Patent Application Publication No. 2010-056470 and Japanese Laid-open Patent Application Publication No. 2010-206025 describe apparatuses configured to perform processing by supplying a processing gas to a circular substrate mounted on a rotary table in a processing chamber, while rotating the substrate.

### SUMMARY OF THE INVENTION

A deposition apparatus according to an embodiment of the present disclosure includes a processing chamber, a rotary table rotatably provided in the processing chamber and including a coolant flow channel therein, a plurality of stages provided along a rotation direction of the rotary table and each configured to mount a substrate thereon, and a heater configured to heat the substrate mounted on each of the stages. The stages are supported by the rotary table while being thermally isolated from the rotary table.

### BRIEF DESCRIPTION OF THE DRAWINGS

Other objects and further features of the present invention will be apparent from the following detailed description when read in conjunction with the accompanying drawings, in which:

FIG. 1 is a schematic cross-sectional view of a deposition apparatus according to an embodiment;

FIG. 2 is a schematic perspective view illustrating a configuration in a processing chamber of the deposition apparatus of FIG. 1;

FIG. 3 is a schematic plan view illustrating the configuration in the processing chamber of the deposition apparatus of FIG. 1;

FIG. 4 is a schematic cross-sectional view of the processing chamber taken along a concentric circle of a rotary table of the deposition apparatus;

FIG. 5 is another schematic cross-sectional view of the deposition apparatus of FIG. 1;

FIG. 6 is a cross-sectional view of the rotary table and a stage;

FIG. 7 is a plan view of the rotary table and the stage;

FIG. 8A and FIG. 8B are cross-sectional views of a rotary table and a stage according to a first modification;

FIG. 9 is a cross-sectional view of a rotary table and a stage according to a second modification; and

FIG. 10 is a cross-sectional view of a rotary table and a stage according to a third modification.

### DESCRIPTION OF THE EMBODIMENTS

In the following, non-limiting exemplary embodiments of the present disclosure will be described with reference to the accompanying drawings. In the accompanying drawings, the same or corresponding members or components are denoted by the same or corresponding reference numerals and the description thereof will not be repeated.

### Deposition Apparatus

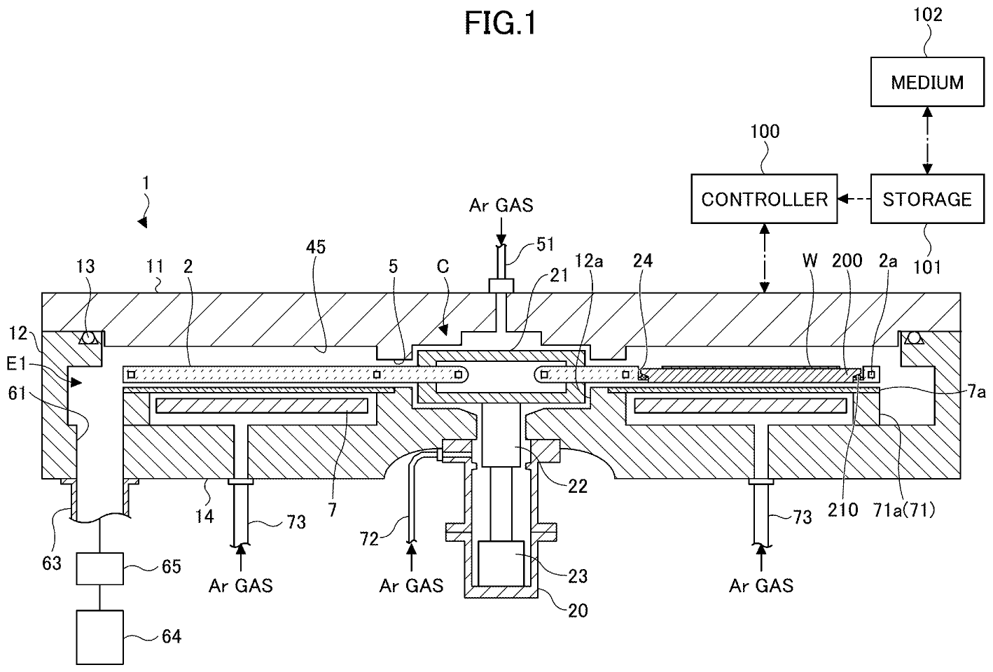

A deposition apparatus according to an embodiment will be described. Referring to FIG. 1 to FIG. 3, the deposition apparatus includes a flat processing chamber 1 having a substantially circular planar shape, and a rotary table 2 rotatably provided in the processing chamber 1 and having a rotational center at the center of the processing chamber 1. The processing chamber 1 includes a chamber body 12 having a cylindrical shape with a bottom, and a top plate 11 airtightly and detachably disposed on the upper surface of the chamber body 12 via a seal member 13 (FIG. 1) such as an O-ring.

The rotary table 2 is fixed to a cylindrical core 21 at a central portion thereof. The core 21 is fixed to the upper end of a rotary shaft 22 extending in the vertical direction. The rotary shaft 22 passes through a bottom 14 of the processing chamber 1. The lower end of the rotary shaft 22 is attached to a drive section 23 that rotates the rotary shaft 22 (FIG. 1) around the vertical axis. The rotary shaft 22 and the drive section 23 are accommodated in a cylindrical case 20 whose upper surface has an opening. A flange provided on the upper surface of the case 20 is airtightly attached to the lower surface of the bottom 14 of the processing chamber 1. This maintains the airtight state of the internal atmosphere of the case 20 with respect to the external atmosphere.

The rotary table 2 has a plurality of circular recesses 24 along the rotation direction (circumferential direction) of the rotary table 2.

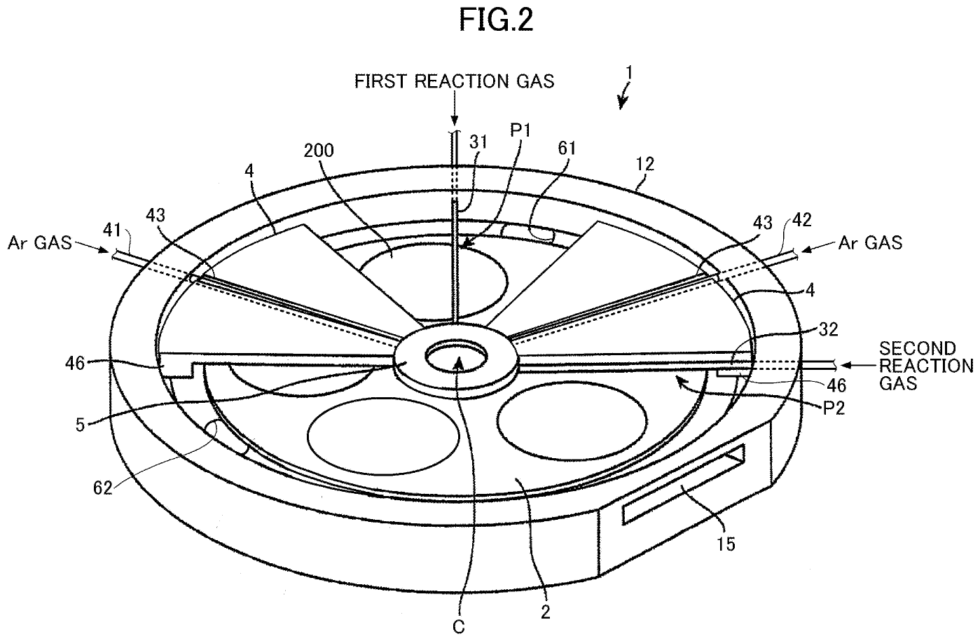

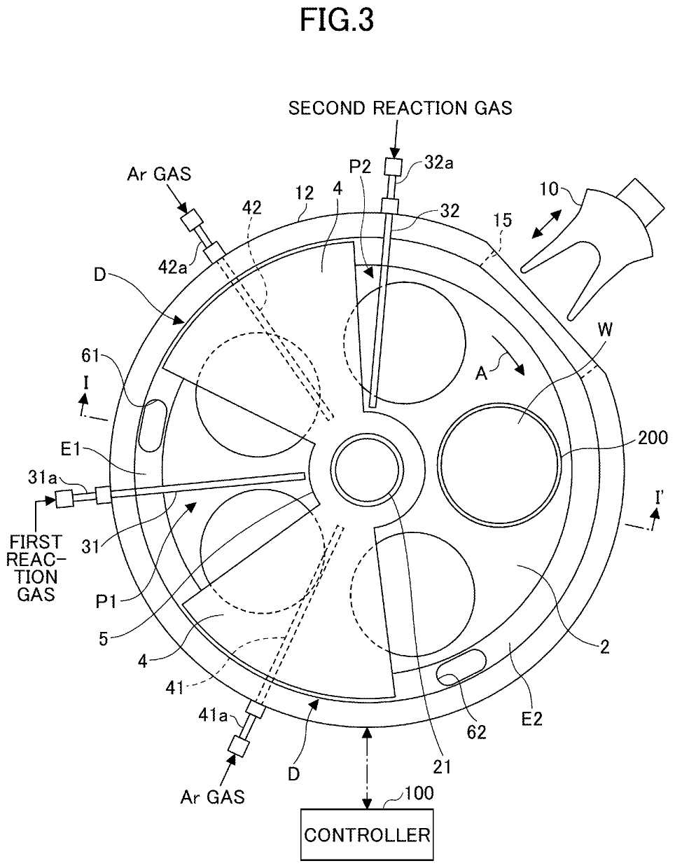

Stages 200 are provided in the respective recesses 24. A substrate W is mounted on each of the stages 200. The substrate W may be, for example, a semiconductor wafer such as a silicon wafer. The stages 200 are supported by the rotary table 2 while being thermally isolated from the rotary table 2. Details of the rotary table 2 and the stages 200 will be described later in detail. In FIG. 2, the substrate W is not depicted, and in FIG. 3, the substrate W is depicted on only one of the stages 200 for convenience.

FIG. 2 and FIG. 3 are diagrams illustrating a configuration in the processing chamber 1. In FIG. 2 and FIG. 3, the top plate 11 is not depicted for convenience of description. As illustrated in FIG. 2 and FIG. 3, reaction gas nozzles 31 and 32 and separation gas nozzles 41 and 42 are spaced from each other along the circumferential direction of the processing chamber 1 above the rotary table 2. In the illustrated example, the separation gas nozzle 41, the reaction gas nozzle 31, the separation gas nozzle 42, and the reaction gas nozzle 32 are provided in this order clockwise (in the rotation direction of the rotary table 2) from a loading port 15 described later. The reaction gas nozzles 31 and 32 and the separation gas nozzles 41 and 42 are formed of quartz, for example. Gas introduction ports 31a, 32a, 41a, and 42a (FIG. 3), located at base ends of the reaction gas nozzles 31 and 32 and the separation gas nozzles 41 and 42, respectively, are fixed to the outer peripheral wall of the chamber body 12. Accordingly, each of the reaction gas nozzles 31 and 32 and the separation gas nozzles 41 and 42 is introduced into the processing chamber 1 from the outer peripheral wall of the processing chamber 1, and is mounted so as to extend horizontally with respect to the rotary table 2 along the radial direction of the chamber body 12.

The reaction gas nozzle 31 is connected to a source (not illustrated) of a first reaction gas via a pipe, a flow rate controller, and the like (not illustrated). The first reaction gas may be, for example, an aminosilane-based gas. Examples of the aminosilane-based gas include diisopropylaminosilane (DIPAS) and tris(dimethylamino)silane (3DMAS).

The reaction gas nozzle 32 is connected to a source (not illustrated) of a second reaction gas via a pipe, a flow rate controller, and the like (none of these are illustrated). The second reaction gas may be, for example, an oxidizing gas. Examples of the oxidizing gas include ozone gas.

Each of the reaction gas nozzles 31 and 32 may be connected to a source of a cleaning gas. The cleaning gas is a gas for removing a film adhering to the interior of the processing chamber 1. The cleaning gas may be, for example, a fluorine-containing gas. Examples of the fluorine-containing gas include fluorine gas and hydrogen fluoride gas. The cleaning gas may be able to be supplied into the processing chamber 1 from a gas nozzle that is provided separately from the reaction gas nozzles 31 and 32.

Each of the separation gas nozzles 41 and 42 is connected to a source (not illustrated) of a separation gas via a pipe, a flow rate control valve, and the like (none of these are illustrated). The separation gas may be, for example, argon (Ar) gas. The separation gas may be nitrogen gas.

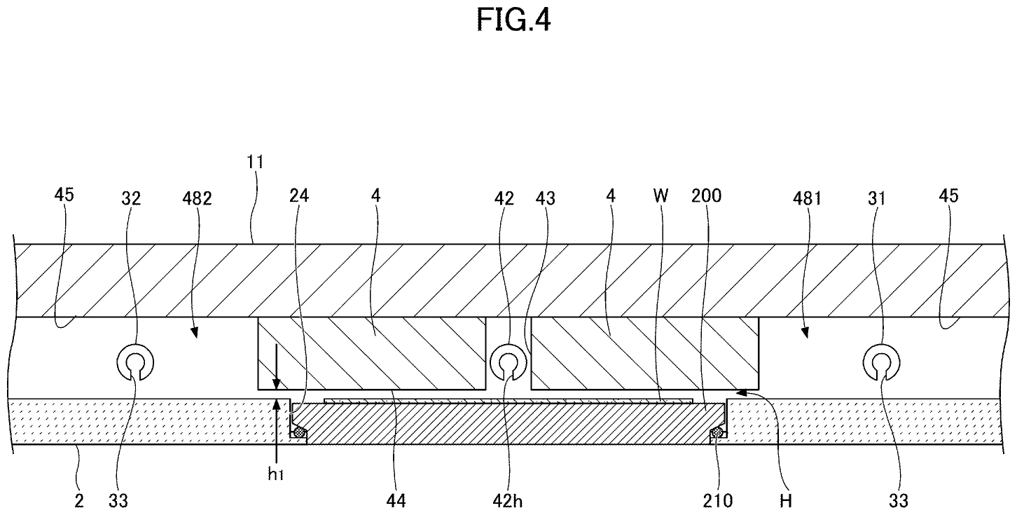

A plurality of gas discharge holes 33 (FIG. 4) facing the rotary table 2 is provided in each of the reaction gas nozzles 31 and 32 at intervals of, for example, 10 mm along the longitudinal direction of each of the reaction gas nozzles 31 and 32. A region below the reaction gas nozzle 31 is a first processing region P1 for adsorbing a Si-containing gas to the substrate W. A region below the reaction gas nozzle 32 is a second processing region P2 for oxidizing the Si-containing gas adsorbed to the substrate W in the first processing region P1.

Referring to FIG. 2 and FIG. 3, two projecting portions 4 are provided in the processing chamber 1. The projecting portions 4 together with the separation gas nozzles 41 and 42 constitute a separation region D. For this reason, the projecting portions 4 are attached to the back surface of the top plate 11 so as to protrude toward the rotary table 2, as will be described later. Each of the projecting portions 4 has a circular sector shape whose top portion is cut in an arc shape in a plan view, and is disposed such that the inner arc is connected to a protrusion 5 (described later) and the outer arc extends along the inner circumferential surface of the chamber body 12 of the processing chamber 1.

FIG. 4 illustrates a cross section of the processing chamber 1 taken along a concentric circle of the rotary table 2, from the reaction gas nozzle 31 to the reaction gas nozzle 32. As illustrated in FIG. 4, a projecting portion 4 is attached to the back surface of the top plate 11. Therefore, in the processing chamber 1, there are a flat low ceiling surface 44 (first ceiling surface), which is the lower surface of the projecting portion 4, and a ceiling surface 45 (second ceiling surface), which is higher than the ceiling surface 44 and located on each circumferential side of the ceiling surface 44. The ceiling surface 44 has a circular sector shape whose top portion is cut in an arc shape in a plan view. As illustrated in FIG. 4, a groove 43 is formed in the center portion of the projecting portion 4 in the circumferential direction so as to extend in the radial direction, and the separation gas nozzle 42 is accommodated in the groove 43. A groove 43 is similarly formed in the other projecting portion 4, and the separation gas nozzle 41 is accommodated in the groove 43. The reaction gas nozzles 31 and 32 are respectively provided in spaces 481 and 482 below the higher ceiling surface 45. The reaction gas nozzles 31 and 32 are spaced apart from the ceiling surface 45, and are provided in the vicinity of the substrate W.

In the separation gas nozzle 42, a plurality of gas discharge holes 42h facing the rotary table 2 is provided at intervals of, for example, 10 mm along the longitudinal direction of the separation gas nozzle 42. Similar to the separation gas nozzle 42, a plurality of gas discharge holes is provided in the separation gas nozzle 41 as well.

The first ceiling surface 44 forms a separation space H, which is a narrow space, with respect to the rotary table 2. When the separation gas is supplied from the gas discharge holes 42h of the separation gas nozzle 42, the separation gas flows toward the space 481 and the space 482 through the separation space H. At this time, because the volume of the separation space H is smaller than the volumes of the spaces 481 and 482, the pressure in the separation space H can be made higher than the pressures in the spaces 481 and 482 by the separation gas. That is, the separation space H having a high pressure is formed between the spaces 481 and 482. Further, the separation gas flowing out from the separation space H into the spaces 481 and 482 acts as a counterflow with respect to the first reaction gas from the first processing region P1 and the second reaction gas from the second processing region P2. For this reason, the first reaction gas from the first processing region P1 and the second reaction gas from the second processing region P2 are separated by the separation space H. This prevents the first reaction gas and the second reaction gas from mixing and reacting with each other in the processing chamber 1.

A height h1 of the ceiling surface 44 with respect to the upper surface of the rotary table 2 is set to a height suitable to make the pressure in the separation space H higher than the pressures in the spaces 481 and 482, by taking into consideration, for example, the pressure in the processing chamber 1 during deposition, the rotation speed of the rotary table 2, the amount of the separation gas to be supplied, and the like.

The protrusion 5 (FIG. 2 and FIG. 3), surrounding the outer periphery of the core 21 that fixes the rotary table 2, is provided on the lower surface of the top plate 11. The protrusion 5 is, for example, continuous with a portion on the rotation center side of the projecting portion 4, and the lower surface of the protrusion 5 is at the same height as the ceiling surface 44.

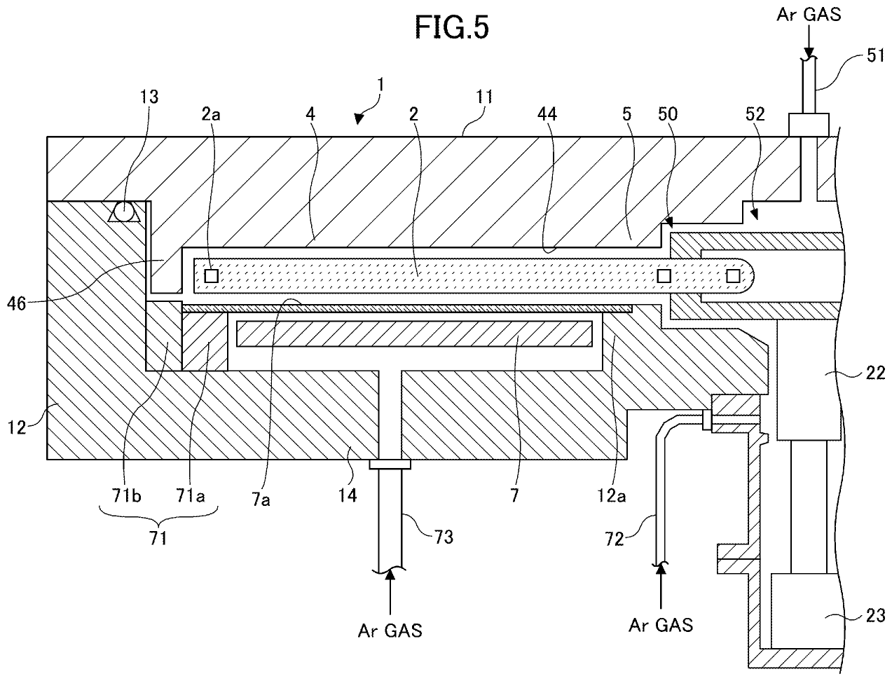

FIG. 1 referred to above is a cross-sectional view taken along the line I-I′ of FIG. 3, and illustrates a region where the ceiling surface 45 is located. Conversely, FIG. 5 is a cross-sectional view illustrating a region where the ceiling surface 44 is located. As illustrated in FIG. 5, a bend 46 that bends in an L-shape so as to face the outer end surface of the rotary table 2 is formed at a peripheral edge portion of the circular-sector-shaped projecting portion 4 (a portion on the outer edge of the processing chamber 1). Similar to the projecting portion 4, the bend 46 suppresses entry of the reaction gases from both sides of the separation region D and suppresses mixing of the reaction gases. The circular-sector-shaped projecting portion 4 is provided on the top plate 11, and the top plate 11 can be removed from the chamber body 12. Therefore, there is a slight gap between the outer peripheral surface of the bend 46 and the chamber body 12. A gap between the inner peripheral surface of the bend 46 and the outer end surface of the rotary table 2, and the gap between the outer peripheral surface of the bend 46 and the chamber body 12 can be set to the same dimension as, for example, the height of the ceiling surface 44 relative to the upper surface of the rotary table 2.

The inner peripheral surface of the chamber body 12 in the separation region D is formed in a vertical plane close to the outer peripheral surface of the bend 46 as illustrated in FIG. 5. Portions of the inner peripheral surface of the chamber body 12 in regions other than the separation region D are recessed outward from a portion facing the outer end surface of the rotary table 2 to the bottom 14 as illustrated in FIG. 1, for example. Hereinafter, for convenience of description, the recessed portion having a generally rectangular cross-sectional shape will also be referred to as an exhaust region. Specifically, an exhaust region communicating with the first processing region P1 is referred to as a first exhaust region E1, and a region communicating with the second processing region P2 is referred to as a second exhaust region E2. As illustrated in FIG. 1 to FIG. 3, a first exhaust port 61 and a second exhaust port 62 are formed at bottom portions of the first exhaust region E1 and the second exhaust region E2, respectively. As illustrated in FIG. 1, the first exhaust port 61 and the second exhaust port 62 are each connected to a vacuum pump 64 via an exhaust pipe 63. The exhaust pipe 63 is provided with a pressure controller 65.

As illustrated in FIG. 1 and FIG. 5, a heater unit 7 is provided in a space between the rotary table 2 and the bottom 14 of the processing chamber 1. The heater unit 7 is configured to heat the substrate W on the rotary table 2 via the rotary table 2 to a temperature (for example, 450° C.) determined by a process recipe. A ring-shaped cover member 71 is provided under the vicinity of the peripheral edge of the rotary table 2 (FIG. 5). The cover member 71 partitions the atmosphere from a space above the rotary table 2 to the exhaust regions E1 and E2, and the atmosphere in which the heater unit 7 is provided, thereby suppressing entry of the gas into a region under the rotary table 2. The cover member 71 includes an inner member 71a and an outer member 71b. The inner member 71a is disposed to face, from under the rotary table 2, the outer edge portion of the rotary table 2 and a region located outward relative to the outer edge portion of the rotary table 2. The outer member 71b is provided between the inner member 71a and the inner peripheral surface of the processing chamber 1. The outer member 71b is provided in proximity to and under the bend 46 formed at the outer edge portion of the projecting portion 4 in the separation region D. The inner member 71a surrounds the entire circumference of the heater unit 7 under the outer edge portion of the rotary table 2 (and under the region located slightly outward relative to the outer edge portion of the rotary table 2).

The bottom 14, at a portion closer to the rotation center than the space in which the heater unit 7 is disposed, includes a protruding portion 12a that protrudes upward so as to approach the core 21 in the vicinity of the center portion of the lower surface of the rotary table 2. A narrow space is formed between the protruding portion 12a and the core 21, and a narrow space (or a gap) is formed between the inner peripheral surface of a through hole penetrating the bottom 14 and the rotary shaft 22. These narrow spaces communicate with the case 20. The case 20 is provided with a purge gas supply pipe 72 that supplies a purge gas to the narrow spaces to purge the narrow spaces. The purge gas may be, for example, argon gas. The purge gas may be nitrogen gas. A plurality of purge gas supply pipes 73, for supplying the purge gas to the space in which the heater unit 7 is disposed to purge the space, are provided in the bottom 14 of the processing chamber 1 under the heater unit 7 at predetermined angular intervals in the circumferential direction. One purge gas supply pipe 73 is depicted in FIG. 5. A lid member 7a is disposed between the heater unit 7 and the rotary table 2 in order to prevent the gas from entering the space in which the heater unit 7 is disposed. The lid member 7a circumferentially covers a region between the inner peripheral surface of the outer member 71b (the upper surface of the inner member 71a) and the upper end of the protruding portion 12a. The lid member 7a can be made of, for example, quartz.

A separation gas supply pipe 51 is connected to the center portion of the top plate 11 of the processing chamber 1. The separation gas supply pipe 51 supplies the separation gas into a space 52 between the top plate 11 and the core 21. The separation gas supplied into the space 52 is discharged toward the peripheral edge of the rotary table 2 along the surface, on the side on which the substrate W is mounted, of the rotary table 2 through a narrow space 50 between the protrusion 5 and the rotary table 2. The space 50 can be maintained at a pressure higher than the pressures in the spaces 481 and 482 by the separation gas. For this reason, the space 50 prevents the first reaction gas, to be supplied into the first processing region P1, and the second reaction gas, to be supplied into the second processing region P2, from passing through a central region C and being mixed with each other. That is, the space 50 (or the central region C) functions similarly to the separation space H (or the separation region D).

As illustrated in FIG. 2 and FIG. 3, the loading port 15 that is used to transfer the substrate W between an external transfer arm 10 and rotary table 2 is formed in the side wall of the processing chamber 1. The loading port 15 is opened and closed by a gate valve (not illustrated). The substrate W is transferred to/from the transfer arm 10 at a position facing the loading port 15. A lifting pin (not illustrated) that raises and lowers the substrate W from the back surface through a corresponding recess 24 and its lifting mechanism (not illustrated) are provided at a portion corresponding to the transfer position under the rotary table 2.

As illustrated in FIG. 1, the deposition apparatus includes a controller 100 including a computer and configured to control the operation of the entire deposition apparatus. A memory of the controller 100 stores a program for causing the deposition apparatus to perform a deposition method, which will be described later, as controlled by the controller 100. The program is embedded with a group of steps so as to perform the deposition method, which will be described later. The program is stored in a medium 102, such as a hard disk, a compact disk, a magneto-optical disc, a memory card, a flexible disk, or the like, is read into a storage 101 by a predetermined reader, and installed in the controller 100.

### Rotary Table and Stage

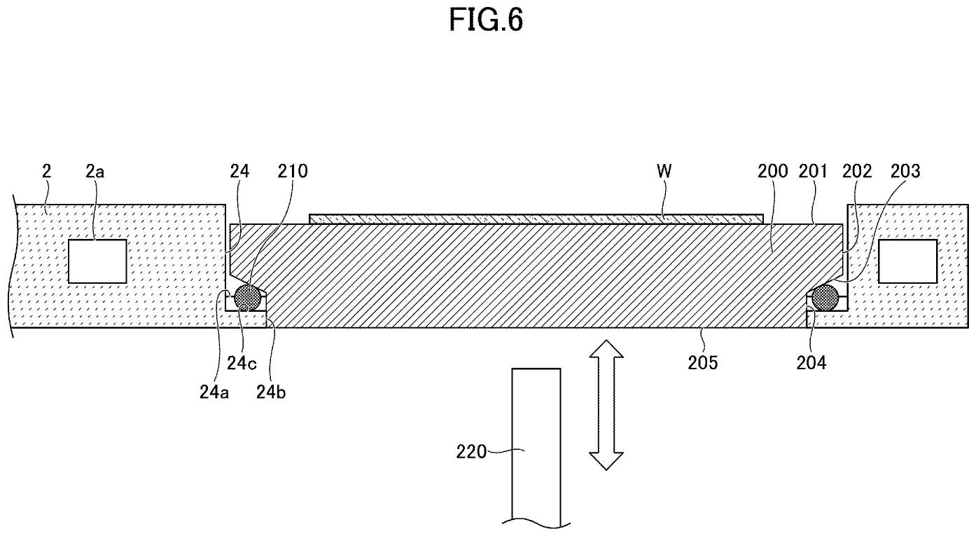

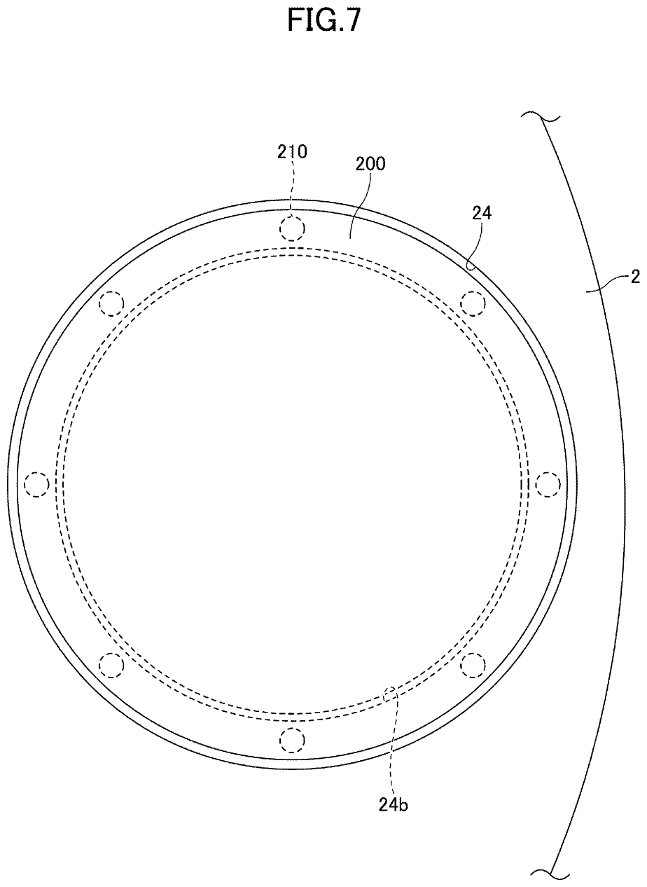

The rotary table 2 and a stage 200 will be described with reference to FIG. 6 and FIG. 7. FIG. 6 is a cross-sectional view of the rotary table 2 and the stage 200. FIG. 7 is a plan view of the rotary table 2 and the stage 200. The substrate W is not depicted in FIG. 7.

The rotary table 2 includes a coolant flow channel 2a therein. A coolant flows through the coolant flow channel 2a. Accordingly, the rotary table 2 is cooled. The coolant may be a liquid or a gas. The coolant may be, for example, Galden.

The rotary table 2 is formed of a material having a high thermal conductivity, for example. In this case, the entirety of the interior of the rotary table 2 is easily cooled uniformly by the coolant flowing through the coolant flow channel 2a. The rotary table 2 may be formed of a material having corrosion resistance or a material subjected to corrosion resistance surface treatment. In such a case, when deposits adhering to the interior of the processing chamber 1 are removed by using the cleaning gas, corrosion of the surface of the rotary table 2 due to the cleaning gas can be suppressed. Examples of the corrosion resistance surface treatment include anodization and ceramic spraying. In the present embodiment, the rotary table 2 is formed of aluminum. However, the rotary table 2 may be formed of metal such as an aluminum alloy or ceramic such as alumina or aluminum nitride.

The rotary table 2 has the plurality of recesses 24. The recesses 24 are provided along the rotation direction of the rotary table 2. Each of the recesses 24 has a circular shape in a plan view. Each of the recesses 24 has an opening 24b. A plurality of grooves 24c is provided in a bottom surface 24a of each of the recesses 24 along the circumferential direction of each of the recesses 24. The grooves 24c may be provided at equal intervals in the circumferential direction of each of the recesses 24. The grooves 24c extend along the radial direction of each of the recesses 24. The bottom surfaces of the grooves 24c may be, for example, horizontal surfaces. A support 210 having a spherical shape is provided in each of the grooves 24c. The support 210 supports a peripheral edge portion of the stage 200. The support 210 may be movable within each of the grooves 24c along the radial direction of the stage 200. The support 210 is a separate member from the rotary table 2. The support 210 may be formed of a material having a thermal conductivity lower than those of the rotary table 2 and the stage 200. The support 210 is formed of, for example, alumina or zirconia.

The stage 200 has a circular shape in a plan view. The stage 200 has amounting surface 201, an upper side surface 202, an inclined side surface 203, a lower side surface 204, and a bottom surface 205.

The substrate W is mounted on the mounting surface 201. The diameter of the mounting surface 201 may be larger than the diameter of the substrate W. The diameter of the mounting surface 201 may be larger than the diameter of the opening 24b and smaller than the inner diameter of a corresponding recess 24. The mounting surface 201 may be flat, for example. The mounting surface 201 may have a recess for mounting the substrate W therein. The recess may have an inner diameter slightly larger than the diameter of the substrate W, and may have a depth substantially equal to the thickness of the substrate W.

The upper side surface 202 faces the inner surface of the recess 24 with a slight gap therebetween. With this configuration, contact between the inner surface of the rotary table 2 and the upper side surface 202, which may be caused by a difference in thermal expansion coefficient between the rotary table 2 and the stage 200, can be suppressed. As a result, generation of particles can be suppressed.

The inclined side surface 203 is located between the upper side surface 202 and the lower side surface 204. The inclined side surface 203 is in point contact with the support 210. Thus, the stage 200 is supported by the rotary table 2 while being thermally isolated from the rotary table 2. The inclined side surface 203 is inclined inward from the upper side surface 202 toward the lower side surface 204. In this case, the center of the stage 200 supported by the support 210 is automatically adjusted to coincide with the center of the recess 24.

The lower side surface 204 is located below the inclined side surface 203. The lower side surface 204 is located inward relative to the upper side surface 202. The lower side surface 204 faces the opening 24b of the recess 24 with a slight gap therebetween. With this configuration, contact between the inner surface of the rotary table 2 and the lower side surface 204, which may be caused by a difference in thermal expansion coefficient between the rotary table 2 and the stage 200, can be suppressed. As a result, generation of particles can be suppressed.

The bottom surface 205 may be parallel to the mounting surface 201. The bottom surface 205 may be exposed from the opening 24b. The diameter of the bottom surface 205 may be smaller than the diameter of the mounting surface 201.

The stage 200 is formed of a material having a high thermal conductivity, for example. In this case, the entirety of the interior of the stage 200 is heated uniformly. Thus, the in-plane uniformity of the temperature of the substrate W mounted on the stage 200 is improved. The stage 200 may be formed of a material having corrosion resistance or a material subjected to corrosion resistance surface treatment. In such a case, when deposits adhering to the interior of the processing chamber 1 are removed by using the cleaning gas, corrosion of the surface of the stage 200 by the cleaning gas can be suppressed. Examples of the corrosion resistance surface treatment include anodization and ceramic spraying. In the present embodiment, the stage 200 is formed of aluminum nitride. However, the stage 200 may be formed of silicon carbide, carbon, or boron nitride. The stage 200 and the rotary table 2 may be formed of different materials or may be formed of the same material.

A lifting rod 220 may be provided under the stage 200. The lifting rod 220 may be liftable and rotatable by a drive device (not illustrated). The lifting rod 220 is moved up so as to contact the bottom surface 205 of the stage 200 exposed from the opening 24b of the rotary table 2, thereby lifting the stage 200 from the rotary table 2. The lifting rod 220 is rotated while lifting the stage 200 so as to rotate the stage 200 relative to the rotary table 2. The lifting rod 220 is not necessarily provided.

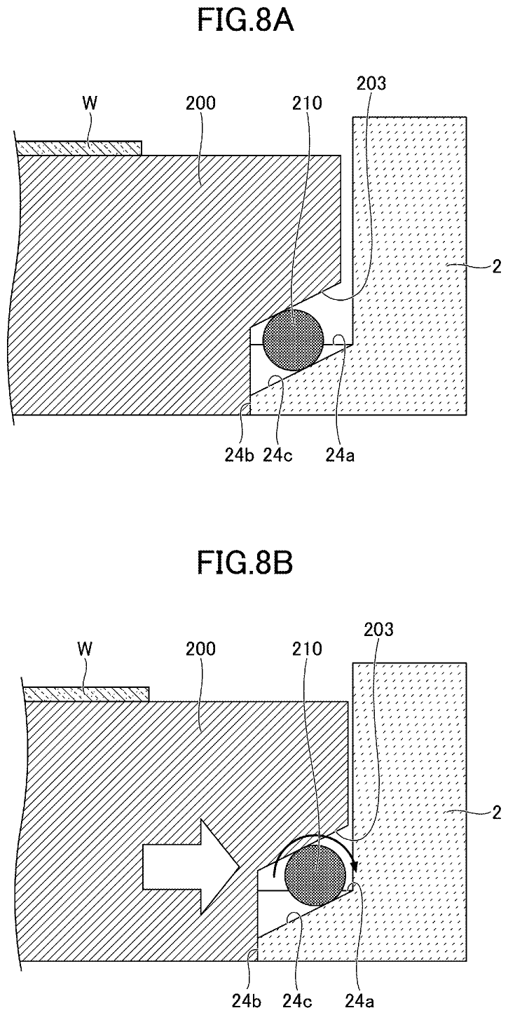

In the example illustrated in FIG. 6 and FIG. 7, the bottom surfaces of the grooves 24c are horizontal surfaces. However, for example, as illustrated in FIG. 8A, the bottom surface of each of the grooves 24c may be an inclined surface that is inclined upward from the inner side toward the outer side of the recess 24. In this case, as illustrated in FIG. 8B, when the stage 200 is thermally expanded, the support 210 rolls up on the inclined surface. The inclined side surface 203 is in point contact with the support 210 in this case as well. Therefore, the stage 200 is supported by the rotary table 2 while being thermally isolated from the rotary table 2. FIG. 8A and FIG. 8B are cross-sectional views of a rotary table 2 and a stage 200 according to a first modification.

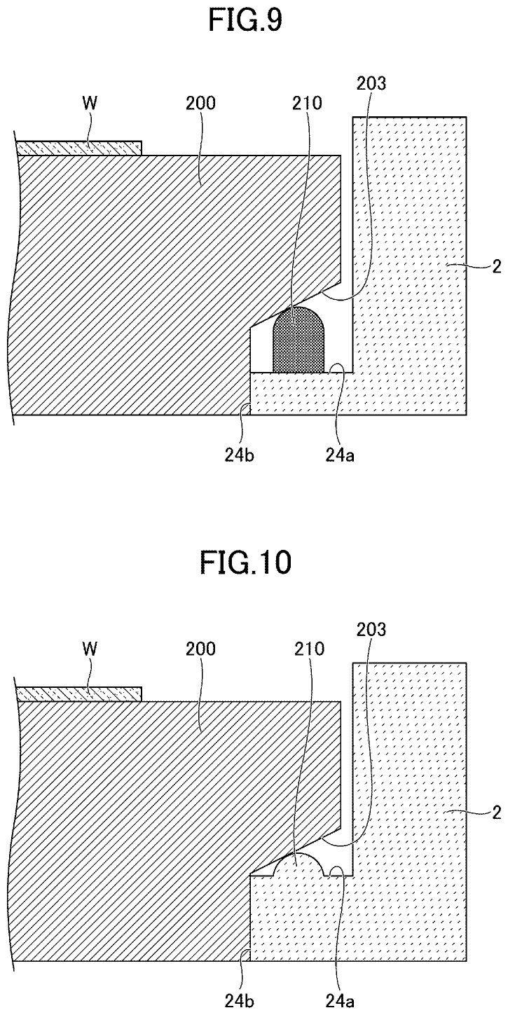

In the example illustrated in FIG. 6 and FIG. 7, the support 210 has a spherical shape. However, as illustrated in FIG. 9, the support 210 may have a pin shape and may be fixed to the bottom surface 24a of the recess 24. The inclined side surface 203 is in point contact with the support 210 in this case as well. Therefore, the stage 200 is supported by the rotary table 2 while being thermally isolated from the rotary table 2. FIG. 9 is a cross-sectional view of a rotary table 2 and a stage 200 according to a second modification.

In the example illustrated in FIG. 6 and FIG. 7, the support 210 is a separate member from the rotary table 2. However, as illustrated in FIG. 10, the rotary table 2 and the support 210 may be formed as one seamless component, and the support 210 may protrude upward from the bottom surface 24a of the recess 24 of the rotary table 2. The inclined side surface 203 is in point contact with the support 210 in this case as well. Therefore, the stage 200 is supported by the rotary table 2 while being thermally isolated from the rotary table 2. FIG. 10 is a cross-sectional view of a rotary table 2 and a stage 200 according to a third modification.

### Processing Method

Processes (a processing method) performed by the deposition apparatus according to an embodiment will be described. In the processing method according to the embodiment, each time a deposition process of forming a film on the substrate W is repeated, a cleaning process of removing a film adhering to the interior of the processing chamber 1 is performed.

### Deposition Process

In the deposition process, the gate valve (not illustrated) is opened, and the substrate W is transferred into the recess 24 of the rotary table 2 through the loading port 15 by the transfer arm 10 from the outside. The substrate W is transferred by raising and lowering the lifting pin (not illustrated) from the bottom side of the processing chamber 1 through a through hole in the bottom surface of the recess 24 when the recess 24 is stopped at a position facing the loading port 15. The transfer of the substrate W is repeated while the rotary table 2 is rotated intermittently, and five substrates W are placed in five recesses 24 of the rotary table 2, respectively.

Next, the gate valve is closed, and the inside of the processing chamber 1 is evacuated to the attainable vacuum degree by the vacuum pump 64. Next, the argon gas is discharged at a predetermined flow rate from the separation gas nozzles 41 and 42, and the argon gas is also discharged at a predetermined flow rate from the separation gas supply pipe 51 and from the purge gas supply pipes 72 and 72. Accordingly, the inside of the processing chamber 1 is controlled to a predetermined pressure by the pressure controller 65. Next, the substrate W is heated to a predetermined temperature by the heater unit 7 while the rotary table 2 is rotated clockwise at a predetermined rotation speed. Further, the coolant is supplied into the coolant flow channel 2a to cool the rotary table 2. Subsequently, the aminosilane-based gas is supplied from the reaction gas nozzle 31, and the oxidizing gas is supplied from the reaction gas nozzle 32.

By rotation of the rotary table 2, the substrate W passes through the first processing region P1, the separation region D, the second processing region P2, and the separation region D, repeatedly in this order. In the first processing region P1, molecules of the aminosilane-based gas are adsorbed on the surface of the substrate W, and a molecular layer of organoaminosilane is formed. After passing through the separation region D, in the second processing region P2, the aminosilane-based gas adsorbed on the surface of the substrate W is oxidized by molecules of the oxidizing gas, and a silicon oxide film is formed. When the above-described process is repeated, a silicon oxide film having a desired thickness is formed.

Thereafter, the supply of the aminosilane-based gas from the reaction gas nozzle 31 is stopped, and the supply of the oxidizing gas from the reaction gas nozzle 32 is stopped. Then, the substrate W mounted on the rotary table 2 is unloaded from the processing chamber 1 in an order reverse to the order of mounting the substrate W on the rotary table 2.

### Cleaning Process

The cleaning process may be performed in a state in which the substrate W is not present in the processing chamber 1. In the cleaning process, with the gate valve being closed, the processing chamber 1 is evacuated to the attainable vacuum degree by the vacuum pump 64. Next, the argon gas is discharged at a predetermined flow rate from the separation gas nozzles 41 and 42, and the argon gas is also discharged at a predetermined flow rate from the separation gas supply pipe 51 and from the purge gas supply pipes 72 and 72. Accordingly, the inside of the processing chamber 1 is controlled to a predetermined pressure by the pressure controller 65. Next, the stage 200 is heated to a predetermined temperature by the heater unit 7 while the rotary table 2 is rotated clockwise at a predetermined rotation speed. In the cleaning process, the coolant is not required to be supplied into the coolant flow channel 2a. Thereafter, the cleaning gas is supplied from the reaction gas nozzles 31 and 32. The cleaning gas may be supplied from one of the reaction gas nozzles 31 and 32.

By rotation of the rotary table 2, the parts of the rotary table 2 pass through the first processing region P1, the separation region D, the second processing region P2, and the separation region D, repeatedly in this order. In the first processing region P1 and the second processing region P2, the surface of the rotary table 2 is exposed to the cleaning gas, and as a result, a film adhering to the rotary table 2 is removed. At this time, the coolant is not supplied into the coolant flow channel 2a, and thus, the rotary table 2 is not cooled. Therefore, the film adhering to the rotary table 2 can be easily removed. The rotation of the rotary table 2 is continued until, for example, the film adhering to the surface of the rotary table 2 is removed.

After the film adhering to the surface of the rotary table 2 is removed, the supply of the cleaning gas from the reaction gas nozzles 31 and 32 is stopped.

According to the embodiment, the coolant flow channel 2a is provided in the rotary table 2, and the stage 200 is supported by the rotary table 2 while being thermally isolated from the rotary table 2. With this configuration, in the deposition process, the rotary table 2 can be cooled by the coolant supplied into the coolant flow channel 2a, while the substrate W placed on the stage 200 is being heated by the heater unit 7. Accordingly, energy required for chemical adsorption of a source gas is obtained on the surface of the substrate W, whereas energy required for chemical adsorption of the source gas is unlikely to be obtained on the surface of the rotary table 2. Therefore, while ensuring adsorption of the source gas onto the surface of the substrate W, adsorption of the source gas onto the surface of the rotary table 2 can be suppressed. As a result, in the deposition process, deposition of a film onto the rotary table 2 in a region where the substrate W is not present can be suppressed.

Further, according to the embodiment, energy required for chemical adsorption of the source gas is not obtained in a region other than the surface of the substrate W, and the amount of the source gas consumed in the region other than the surface of the substrate W is reduced. Therefore, the range where a film is deposited is limited to the substrate W and the vicinity of the substrate W. Accordingly, the following effects can be obtained.
(a) The range where film peeling occurs is narrow, and the probability of generation of particles can be reduced.
(b) The range where a film is removed by cleaning is narrow, and the amount of the cleaning gas consumed can be reduced.
(c) The temperature and concentration are uniform in a deposition range, and the etching rate of cleaning is easily controlled.
(d) The temperature gradient between the stage 200 and the rotary table 2 increases by the thermal isolation structure, and thus, a non-uniform deposition range is reduced and an over-etched portion is reduced.
(e) When a film is formed on a substrate W having a pattern on the surface thereof, the amount of the source gas supplied into the pattern increases, and thus, the film thickness uniformity and the step coverage in the pattern are improved.

Further, according to the embodiment, the heat capacity of an object to be heated (the stage 200) is small. Accordingly, the following effects can be obtained.
(f) The power consumption of the heater unit 7 can be reduced.
(g) The temperature rise and fall time in the deposition process and the cleaning process is shortened, and thus, the production efficiency is improved.

Further, according to the embodiment, the stage 200 is supported by the rotary table 2 while being thermally isolated from the rotary table 2. Accordingly, the following effects can be obtained. (h) The size of the object to be heated (the stage 200) is small and the temperature distribution inside the object to be heated is small. Thus, a material having a low thermal stress resistance can be selected as the material of the stage 200. For example, a material having a high resistance to the cleaning gas or plasma, or a low-cost material can be selected.
(i) In the cleaning process, the rotary table 2 can be cooled while the stage 200 is being heated. Thus, the etching of the rotary table 2 can be suppressed. Therefore, the frequency of replacement of rotary tables 2 can be reduced.

According to the present disclosure, deposition of a film onto a rotary table in a region where a substrate is not present can be suppressed.

While certain embodiments have been described, these embodiments should be considered to be exemplary in all respects and not restrictive. Furthermore, The above-described embodiments may be omitted, substituted, or modified in various forms without departing from the scope and spirit of the appended claims.

What is claimed is:

1. A deposition apparatus comprising:
a processing chamber;
a rotary table rotatably provided in the processing chamber, the rotary table including a coolant flow channel therein;
a plurality of stages provided along a rotation direction of the rotary table, and each configured to mount a substrate thereon; and
a heater configured to heat the substrate mounted on each of the stages;
wherein the stages are supported by the rotary table while being thermally isolated from the rotary table.

2. The deposition apparatus according to claim 1, further comprising:
a plurality of supports provided on the rotary table along a circumferential direction of each of the stages, and configured to support each of the stages,
wherein each of the stages is in point contact with the plurality of supports.

3. The deposition apparatus according to claim 2, wherein the supports are separate members from the rotary table.

4. The deposition apparatus according to claim 3, wherein the supports are movable along a radial direction of each of the stages.

5. The deposition apparatus according to claim 3, wherein the supports are fixed to the rotary table.

6. The deposition apparatus according to claim 2, wherein the rotary table and the supports are formed as one seamless component.

7. The deposition apparatus according to claim 2, wherein the rotary table has a plurality of recesses along the rotation direction of the rotary table,
an inner diameter of each of the recesses is larger than a diameter of each of the stages, and
the supports are provided on a bottom surface of each of the recesses, and are configured to support a peripheral edge portion of each of the stages.

8. The deposition apparatus according to claim 7, wherein the bottom surface of each of the recesses has an opening, and
a lower surface of each of the stages is exposed from the opening.

9. The deposition apparatus according to claim 1, wherein the stages are rotatable relative to the rotary table.

10. A processing method performed by a deposition apparatus including
a processing chamber,
a rotary table rotatably provided in the processing chamber, the rotary table including a coolant flow channel therein,
a plurality of stages provided along a rotation direction of the rotary table, and each configured to mount a substrate thereon, and
a heater configured to heat the substrate mounted on each of the stages,
wherein the stages are supported by the rotary table while being thermally isolated from the rotary table, the processing method comprising:
forming a film on the substrate mounted on each of the stages, while supplying a coolant into the coolant flow channel.

11. The processing method according to claim 10, further comprising:
removing a film adhering to an interior of the processing chamber in a state in which supply of the coolant into the coolant flow channel is stopped.
